(19) United States
(12) Patent Application Publication
(10) Pub. No.: US 2002/0064033 A1
(43) Pub. Date: May 30, 2002

(54) Gigabyte memory module and methods for making the same

(75) Inventors: Phillip A. Deane, Durham, NC (US); Mark Windsor Roberson, Cary, NC (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: MCNC, Research Triangle Park, NC (US)

(21) Appl. No.: 09/726,155

(22) Filed: Nov. 29, 2000

(51) Int. Cl. H05K 1/11; H05K 1/14

(52) U.S. Cl. 361/784

(57) ABSTRACT

An electronic memory module, on the order of 1 Gigabyte or more, which is compact, results in minimum transmission delay, and which may be incorporated into existing computer systems. The electronic module for use in memory arrays includes a module substrate, a plurality of daughter boards edge-mounted to the module substrate, wherein each daughter board of the plurality of daughter boards includes a front face and a back face opposite the front face, and at least one memory chip mounted to the front face of each daughter board of the plurality of daughter boards, such that the at least one memory chip is in electrical communication with the module substrate. A method of constructing the memory module having a high data bus bandwidth includes providing a plurality of daughter boards, wherein each daughter board has a front face and a back face opposite the front face, mounting at least one memory chip on the front face of each daughter board of the plurality of daughter boards, and edge-mounting the plurality of daughter boards, to a module substrate, such that the memory chips are in electrical communication with the module substrate thereby forming a memory module.

### FIELD OF THE INVENTION

The present invention relates to a multi-chip package, and more specifically, to an electronic module for use in memory arrays having high data bus bandwidths, including a plurality of memory chips efficiently packaged therein, and methods for making the same.

### BACKGROUND OF THE INVENTION

Dynamic Random Access Memory (DRAM) devices are the most widely used type of memory device. The amount of single-bit addressable memory locations within each DRAM is increasing as the need for greater memory densities increases. Because electrical components are shrinking, there is a need in the art to produce memory devices that are physically smaller and can fit within the packaging requirements of previous generations of memory parts. Currently, the speed at which memory is accessed can severely hinder the processing speed of a computer. As such, there is a need for memory devices which do not slow down the processing speed of today's high speed computers. At the same time, the need for plug-compatible upgrades requires that memory density upgrades be easy to effect in existing computer systems and other systems which use memory, such as video systems. This requires that greater density memory devices be placed within the same size packages as previous generations of memory parts with the same signal and power pinout assignments.

As memory arrays become larger, such as those on the order of 1 Gigabyte or more, innovative packaging and assembly methods are required. For instance, a 1 Gigabyte memory array may comprise thirty two (32) 256 Mbit SLDRAM chips in a 16 Mbit×16 bit configuration. Because a high clock rate may be used, such as 400 MHz, the memory array would require a data bus over 100 bytes wide in order for high performance applications such as video speed graphics or Internet servers, as the information flow measured as cross-sectional bandwidth is relatively high in such applications, generally exceeding 1 GB/sec or even 40 GB/sec for router memory. Furthermore, the memory control interface to the processor would be over 1000I/O pins. To achieve such large packages, conventional memory packages on the order of 1 Gigabyte or more consume a large amount of physical area, and as a result, slow down the processing speed of components with which they operate. Because of the physical dimensions of the packages, memory devices may be located relatively far from processors such that electrical signals take some time to travel between memory device and the processor, merely slowing down the processing speed of the computer or other device in which the memory devices are utilized. Although the delay caused as a result of signal path length has historically not been a large impediment to processing speed, today's computers operate at very high speeds requiring efficient packaging to reduce any delay due to transmission time across the signal paths.

Therefore, a memory array, on the order of 1 Gigabyte or more is needed, which is compact, results in minimum transmission delay, and may be incorporated into existing computer systems.

### SUMMARY OF THE INVENTION

According to one embodiment of the invention, an electronic module for use in memory arrays having high data bus bandwidths is disclosed. The electronic module includes a module substrate, a plurality of daughter boards edge-mounted to the module substrate, wherein each daughter board of the plurality of daughter boards includes a front face and a back face opposite the front face, and at least one memory chip mounted to the front face of each daughter board of the plurality of daughter boards, such that the at least one memory chip is in electrical communication with the module substrate.

The plurality of daughter boards can be stacked adjacent to each other such that the front face of at least one daughter board is located adjacent to the back face of at least one other daughter board. Furthermore, the plurality of daughter boards may be stacked together and substantially aligned to form a compact parallelepiped memory module.

According to one aspect of the invention, the plurality of daughter boards are edge mounted to the module substrate by edge mounted solder joints. Furthermore, the plurality of daughter boards can be in wafer or panel form, and the memory chips can be flip-chip mounted to the front face of each daughter board. The memory chips can also be underfilled on the daughter boards by a filler comprising an adhesive.

According to another aspect of the invention, the plurality of daughter boards comprise routing lines for electrically connecting the memory chips mounted thereon to edges of the plurality of daughter boards. Furthermore, according to one aspect of the invention, a thermal spacer may be placed between at least one memory chip and an adjacent daughter board in spaced relationship with the at least one memory chip, such that the thermal spacer dissipates heat from the electronic module.

According to another embodiment of the invention, there is disclosed a method of constructing a memory module having a high data bus bandwidth. The method includes providing a plurality of daughter boards, wherein each daughter board includes a front face and a back face opposite the front face, mounting at least one memory chip on the front face of each daughter board of the plurality of daughter boards, and edge-mounting the plurality of daughter boards, which carry respective memory chips, to a module substrate, such that the memory chips are in electrical communication with the module substrate thereby forming a memory module.

According to the method, edge-mounting the plurality of daughter boards to the module substrate can include stacking the plurality of daughter boards adjacent to each other such that the front face of at least one daughter board is located adjacent to the back face of at least one other daughter board. Furthermore, edge-mounting the plurality of daughter boards to the module substrate can include soldering the plurality of daughter boards to the module substrate.

According to one aspect of the invention, the memory chips may be mounted to the daughter boards by flip-chip bonding. Additionally, the memory chips may be underfilled after being mounted on the plurality of daughter boards. This underfilling can optionally comprise an adhesive material to strengthen the bond between the two components. According to yet another aspect of the invention, a thermal spacer can be inserted between at least one memory chip and an adjacent daughter board in spaced relationship with the at least one memory chip, wherein the thermal spacer dissipates heat. The thermal spacer may be edge mounted to the module substrate, according to another aspect of the invention. Finally, according to yet another aspect of the invention, the plurality of daughter boards and/or thermal spacers can be stacked together to form a parallelepiped memory module.

It will be appreciated that the memory module of the present invention is relatively compact in size. Therefore, the module fits easily into electronics that require small components. Further, the compact nature of the memory module results in a minimum amount of signal propagation delay when the memory chips are accessed. As a result, as compared to structures offering an equivalent amount of memory (e.g., on the order of one gigabyte), a memory module according to the present invention can increase the speed of electronics in which it is placed, while also requiring less volume.

### BRIEF DESCRIPTION OF THE DRAWINGS

FIG. 1 shows the front face of a memory chip, according to one aspect of the invention.

FIG. 2 shows the back face of a memory chip, according to one aspect of the invention.

FIG. 3 shows a daughter board, upon which a memory chip may be mounted, according to one aspect of the invention.

FIG. 4 shows two memory chips mounted on a daughter board, according to one aspect of the invention.

FIG. 5A shows a side view of a memory module, including a module substrate, daughter boards, and memory modules, according to one aspect of the invention.

FIG. 5B shows a side view of a memory module, including a module substrate, daughter boards, and memory modules, according to another aspect of the invention.

FIG. 6 shows a sheet of daughter boards having memory chips mounted thereon, according to one aspect of the invention.

FIG. 7 shows a perspective view of a memory module, including a module substrate, daughter boards, and memory modules, according to one aspect of the invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

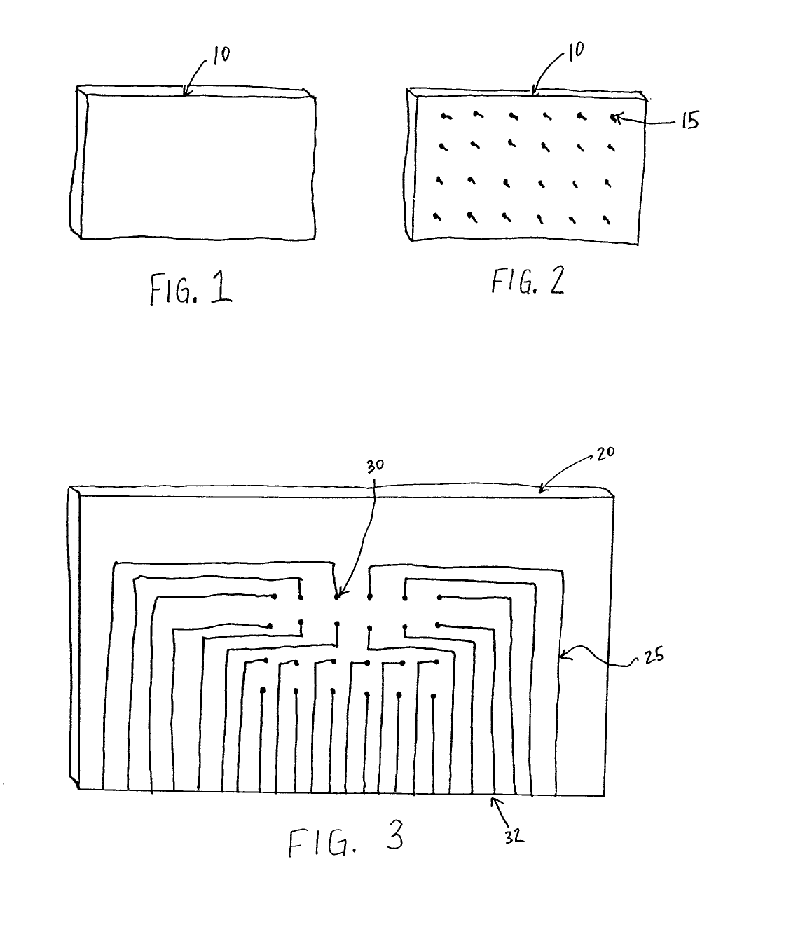

FIG. 1 shows the front face of a memory device, also known as a memory chip, 10, according to one aspect of the invention. The memory chip 10 may be a dynamic random access memory (DRAM) device, a SLDRAM device, or any other type of memory chip. Furthermore, although the present invention will be described herein with reference to packaging multiple memory chips, particularly, DRAM devices, it will be appreciated by those of skill in the art that the present invention may also be utilized to efficiently package any other types of chips, whether analog or digital, and including logic chips, processors, programmable devices, timers, and the like. Because the present invention can efficiently package these devices, such as memory chips, the present invention results in chip modules which are smaller and result in less signal propagation delay than conventional chip packages.

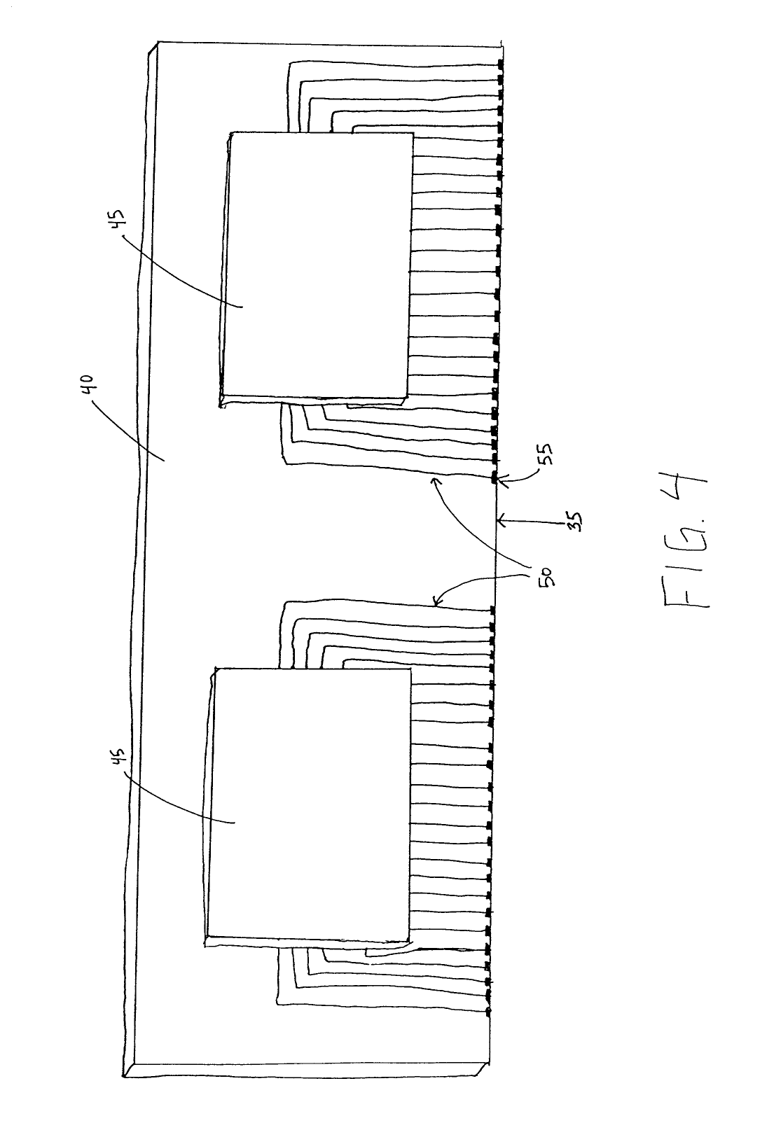

FIG. 2 shows the back face of the chip 10, including pins 15 which extend outwards perpendicularly from the chip 10 to electrically connect the chip 10 to other electrical devices. The plurality of pins 15 located on the chip 10 form a pin grid array, as can be appreciated with reference to the figure. Because the pins 15 do not extend beyond the edges of the body of the chip 10 defining the chip's length and width, the memory chip 10 may be mounted to another device without utilizing an area greater than the body of the chip itself, which is advantageous where minimizing both package size and electrical length of connections is desirable, as in most electrical applications. Therefore, where the chip 10 is mounted on another substrate which is not much larger in size that the chip 10, the combination may be referred to as a chip-sized package or chip-scale package. Although the chip 10 is illustrated as including pins 15 for mounting the chip 10 to another electrical device, it will be appreciated that the chip 10 could also utilize other mechanisms for attachment or mounting. For instance, instead of pins 15, the chip 10 could utilize a ball grid array, as is well known in the art, which also has connections contained wholly within the area of the body of the chip 10 defined by its length and width. Additionally, although the present invention is described herein with respect to chips having a pin grid or ball grid array, chips utilized in the present invention may also be in communication with other electrical components via conventional tape or wire bond leads.

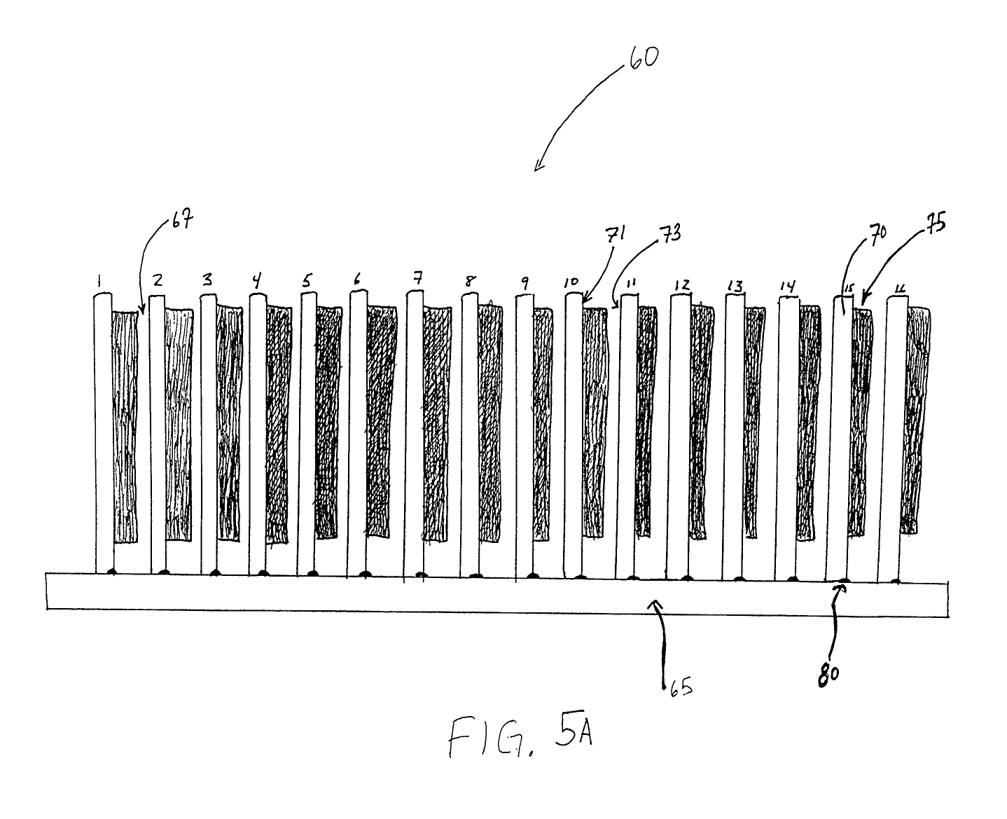

FIG. 3 shows a daughter board 20, upon which the memory chip 10 illustrated in FIGS. 1 and 2 may be mounted. The daughter board 20 can comprise a printed circuit board or similar substrate preferably constructed from of a non-conductive material, such as a non-conductive resin, which is strong enough to support a memory chip 10 thereon. For instance, the daughter board may be constructed out of a FR4 or ceramic material, such as alumina or magnesium oxide. Advantageously, the daughter board 20 includes routing traces 25, which electrically connect the pins 15, or similar attachment mechanisms, to the edge 32 or other connection point of the daughter board 20. Therefore, the traces 25 are preferably constructed of copper, gold, or other conductive materials. The traces 25 generally extend from the center portion of the daughter board 20, where the memory chip 10 is mounted, to the edge 32 of the daughter board 20. These traces may be formed on one or more layers of the daughter board 20, or may be contained entirely within the daughter board 20, as is well known in the art. It should be appreciated that it is advantageous that the routing traces 25 be as short as possible while at the same time establishing a connection which will not result in interference between adjacent traces, because delays from signal propagation over the traces should be minimized. Therefore, the traces 25 shown in FIG. 3 are for illustrative purposes only, as any routing pattern may be utilized to accomplish the connection between the memory chip 10 and the edge 32 of the daughter board 20.

To accurately achieve a connection between the memory chip 10 and the daughter board 20, the ends of the traces which receive the memory chip 10 comprise terminals 30 that accomplish an electrical connection with respective pins of other leads of the chip 10. Therefore, where the chip 10 includes a pin grid array, the terminals 30 can include plated vias or through holes in connection with the traces 25 such that an electrical connection can be achieved when the chip's pins 15 are inserted into respective vias or through holes defined by the daughter board 20. Similarly, where the memory chip 10 includes a ball grid array, the terminals 30 may include pads such that when the ball grid array is heated, a solder connection will form a mechanical and electrical connection with each terminal 30 of the daughter board 20. Furthermore, as noted above, wire or tape leads can also be utilized to electrically connect the chip 10 to the terminals 30 of the traces 25.

FIG. 4 shows two memory chips 45 mounted on a daughter board 40, according to one aspect of the invention. Although the memory chips 45 are both mounted on the same daughter board 40, the chips are electrically isolated from each other. Therefore, the combination of the two memory chips 45 mounted on a single daughter board 40 may also be accomplished using two separate daughter boards, each having a respective memory chip mounted thereon. As stated above, the memory chips 45 can be mounted to the daughter board 40 by any of the methods mentioned above, such as by a pin gird array, ball grid array, other flip-chip bonding methods, or via tab or wire bonds, as are well known in the art. According to one aspect of the invention, after the chips 45 are bonded to the daughter board 40 using one of the above methods, the chips may be underfilled by a filler comprising an adhesive. The adhesive may be injected between the chips 45 and the daughter board 40 after the chips 45 are bonded to the daughter board 40. The filler can make the chip-daughter board combination more mechanically rigid and can also serve to dissipate heat generated by the chips 45. Furthermore, where an adhesive filler is used, the filler helps bonds the memory chip 45 to the daughter board 40.

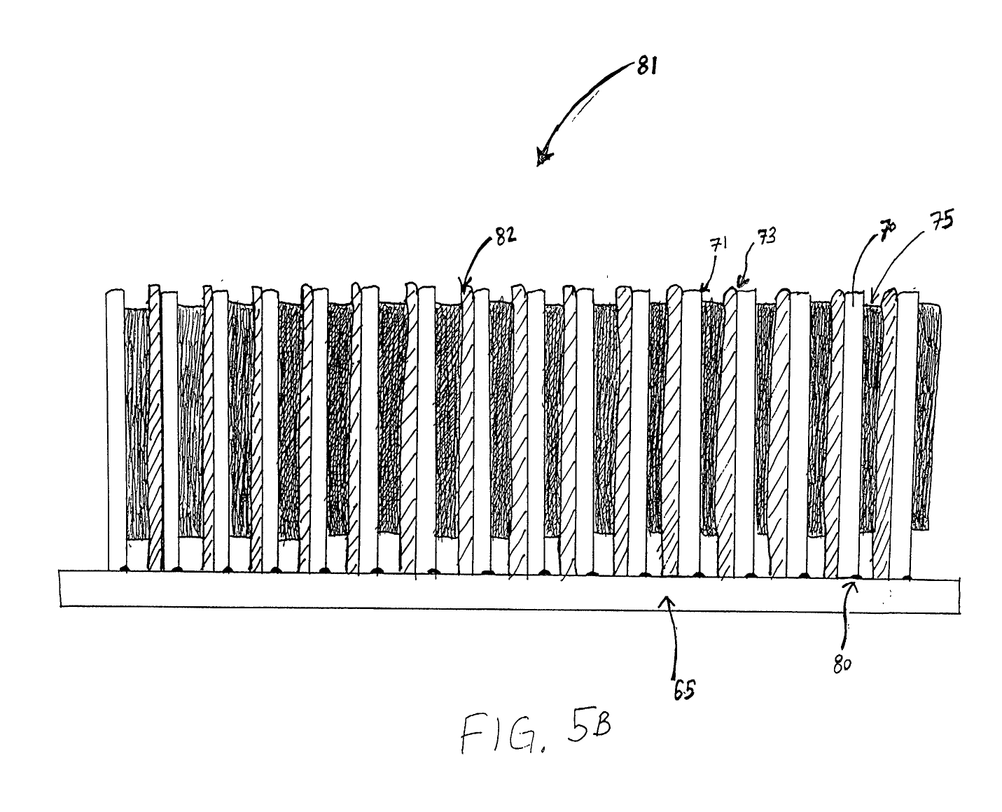

As can be appreciated with reference to FIGS. 2, 3 and 4, the memory chips 45 are electrically connected to an edge 35 or other connection point of the daughter board 40 via routing traces 50. Located at the edge 35 of the daughter board 40 are a plurality of edge connectors 55, which terminate the routing traces 50 at the edge 35 of the daughter board 40. Like the terminals 30, the edge connectors 55 are constructed out of a conductive material, such as copper, gold, or like material, which can transmit electrical signals without substantial loss. The purpose of the edge connectors 55 is to facilitate an electrical connection between the memory chips 45 and an electrical device abutting the edge 35 of the daughter board 40, such as a substrate. As will be described with reference to FIGS. 5 and 7, below, the edge connectors 55 enable a memory module to be constructed which includes a large number of daughter boards 40 and chips 45.

It will be appreciated that although the daughter board 40 is illustrated as containing only two memory chips 45 mounted thereon, the daughter board 40 could also receive a larger number of memory chips 45. For instance, one daughter board 40 could contain 8 or 16 memory chips, placed in a grid or in a row or column format. However, where a large number of chips 45 are placed on one board, the length of at least some of the traces connecting the chip 45 to the device to which it is ultimately connected through edge connectors 55, can be relatively lengthy. This can result in negative consequences. For instance, where routing traces become lengthy, substantial signal propagation delays can occur when some of the more remote memory chips are accessed. Furthermore, where a large number of chips are placed on a single daughter board, the device may be difficult to cool. This will be further appreciated with reference to FIG. 7. Therefore, it is desirable to limit the number of chips mounted on the daughter board to a small number, such as two, as shown in FIG. 4.

FIG. 5A shows a side view of a memory module 60, according to one embodiment of the invention. The memory module 60 includes a module substrate 65, daughter boards 70, and memory chips 75. The plurality of daughter boards 70 are stacked adjacent to each other so that the front face 71 of each daughter board 70 is located adjacent to the back face 73 of at least one other daughter board 70. In the embodiment shown in FIG. 5, the memory chips 75 mounted on each of the respective daughter boards 70 are located between each of the daughter boards 70 in the memory module 60. According to one aspect of the invention, the daughter boards 70 can have two memory chips mounted thereon, as in the embodiment shown in FIG. 4. Therefore, the memory module 60 of FIG. 5 can include 32 total memory chips (16 daughter boards ×2 memory chips per daughter board).

The daughter boards 70 are preferably edge mounted to the module substrate 65 by edge mount solder joints 80. Each of these solder joints 80 may correspond to respective edge connectors located on the daughter board, such as the edge connectors 55 illustrated in FIG. 4, such that the solder joints 80 provide the mechanical connection between the daughter boards 70 and the module substrate 65, and the electrical connection between the memory chips 75 and the module substrate 65. Edge-mounting is disclosed in U.S. Pat. No. 5,963,793, entitled “Microelectronic Packaging Using Arched Solder Columns,” and U.S. Pat. No. 5,793,116, entitled “Microelectronic Packaging Using Arched Solder Columns,” each of which are incorporated herein by reference.

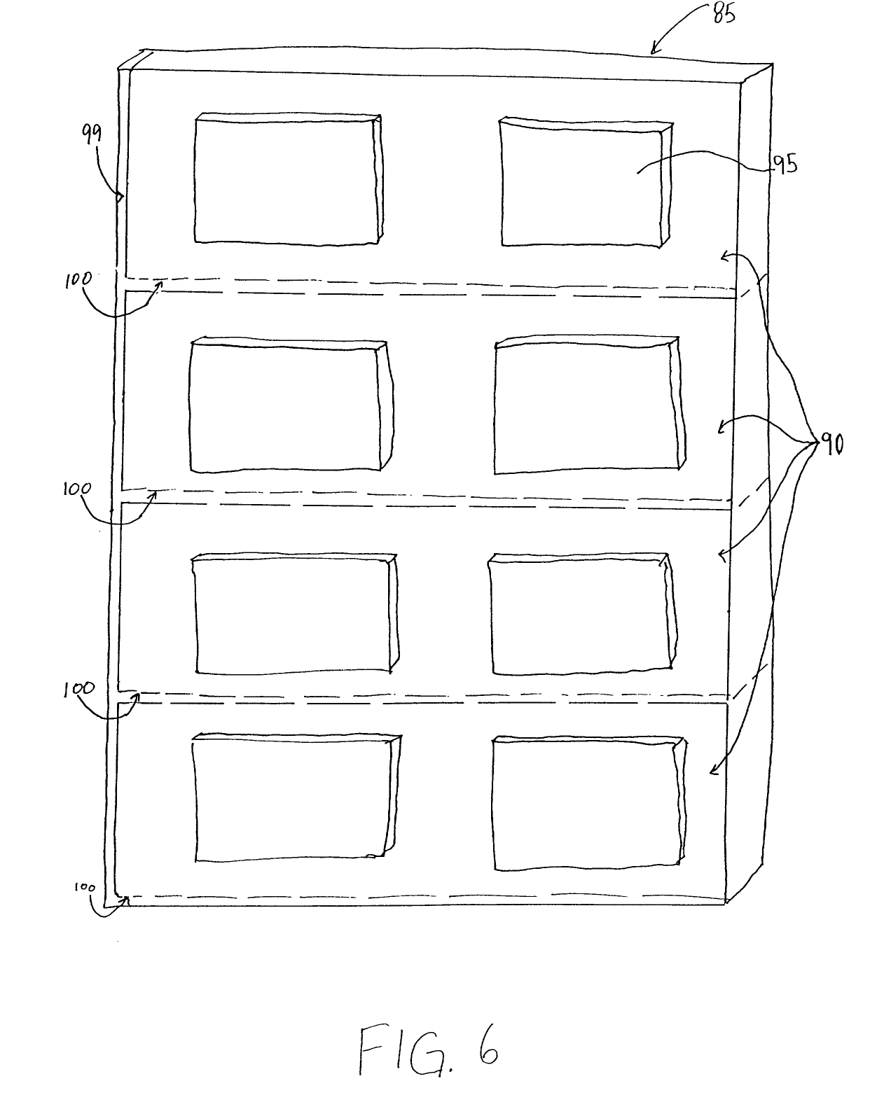

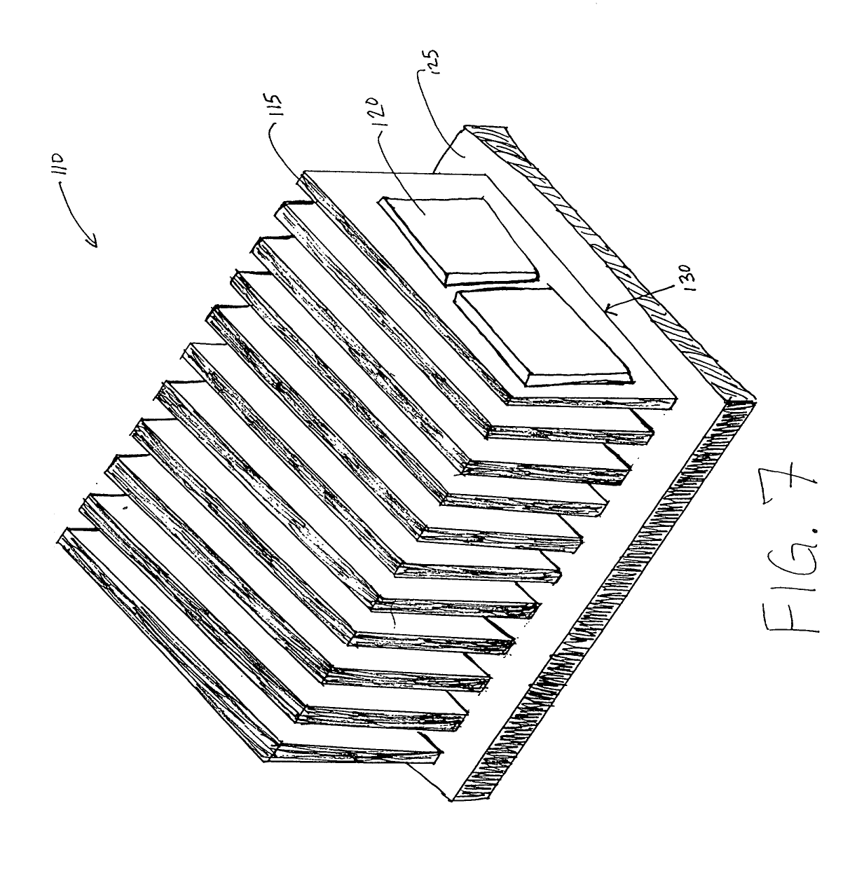

According to one aspect of the invention, an air gap 67 exists between the memory chips 75 and adjacent daughter boards 70. For instance, referring to FIG. 5, the memory chips mounted on the leftmost daughter board are separated from the second leftmost daughter board by an air gap 67. The air gap 67 allows air to flow through the memory module 60, thereby cooling the memory chips 75, daughter boards, 70, and module substrate 65. The memory module 60 offers a number of advantages over conventional memory modules. First, the module 60 is compact, requiring a minimum amount of space. Second, the signal path to any of the memory chips is relatively short, as compared to a memory module having 32 chips in a row or grid pattern. Finally, the structure enables the testing of the memory chips prior to their inclusion in the memory module, as will be discussed with reference to FIG. 6, discussed below.

FIG. 5B shows a side view of a memory module 60, where the memory module 60 includes a module substrate 65, daughter boards 70, thermal spacers 82, and memory chips 75, according to another aspect of the invention. The thermal spacers 82 are located between the memory chips 75 and adjacent daughter boards 70 in spaced relationship with the memory chips 75. The thermal spacers 82 can serve to dissipate the heat generated by components of the module 81, particularly, the memory chips 75. Preferably, the thermal spacers 81 have high thermal conductivity to draw heat away from other components in the memory module 81. For instance, the thermal spacers 82 may be constructed of aluminum nitride, a highly thermally conductive material. However, the thermal spacers 82 may also be constructed of a wide variety of conductive materials, including, but not limited to, FR4 or ceramic materials.

Although the thermal spacers 82 are illustrated as being wedged between and abutting the daughter boards 70 and memory chips 75, the thermal spacers 82 may abut only the memory chips 75 or daughter boards 70, or may be freestanding such that they touch neither the memory chips 75 or daughter boards 70. Additionally, the thermal spacers 82 may exist adjacent to every memory chip 75, or only some of the memory chips 75, such as alternating memory chips 75. Mounting the thermal spacers 82 between alternating memory chips 75 can allow both the thermal spacers 82 and airflow to dissipate heat generated by the memory module's components. According to one aspect of the invention, the thermal spacers 82 may be affixed to memory chips 75 by an adhesive. According to another aspect of the invention, the thermal spacers 82 can be mounted to the module substrate 65 by edge mounted solder joints, which may help to make the entire memory module 60 more rigid so that it may be less susceptible to mechanical failure.

It will also be appreciated that the daughter boards 70 or the thermal spacers 82 in FIGS. 5A or 5B can have different lengths in addition to the illustrated scheme in which they are all substantially the same length. For instance, referring again to FIG. 5A, the elements numbered 1, 2, 3, 4, etc., could be arranged in repeating length patterns such as:

(long, short, short, short)

(long, long, short, short)

(long, short, long, short)

The rationale and advantage of such a scheme is that the laminar and turbulent fluid (liquid or gas) flows that can provide convective cooling of the unit may be advantageously affected by arranging for gaps between tall spacers to allow for more fluid flow velocity.

In order to efficiently fabricate the daughter boards, the daughter boards can be cut from a single sheet. As depicted in FIG. 6, for example, a sheet 85 of daughter boards having memory chips 95 mounted thereon, according to one aspect of the invention, from which individual daughter boards 90. Mounting memory chips 95 onto a number of daughter boards 90 prior to the daughter boards' connection to a module substrate, as in FIG. 5, enables testing of memory chips 95 and the connections between the respective memory chips 95 and daughter boards 100. This is particularly important where a large memory array is to be constructed, as there may be many memory chips within each memory module, and each memory chip is connected to the daughter boards by 100 or more connections. For instance, in conventional memory arrays, where 32 memory chips may be mounted onto one substrate, a minor faulty connection between one memory chip and the substrate may result in a loss of the entire array of memory chips, which would have to be discarded.

According to one aspect of the present invention, memory chips 95 may be mounted onto the daughter boards 90 by one of the methods described with respect to FIGS. 1, 2 and 3, described above. For example, two memory chips having ball grid arrays may be placed on each daughter board 90, after which the entire structure is heated or burned, such that a connection between the memory chip and daughter board 90 is accomplished. After being bonded to the daughter boards 90, which have routing traces thereon, such as in FIG. 4 (the routing traces are not illustrated in FIG. 6), the individual memory chips 95 can be tested. This can be done by connecting a testing device to the routing traces, such as where the traces terminate at an edge of the board 100 after the daughter boards 90 are diced, or cut, from the sheet 85. For example, the testing device may be constructed such that it is in communication with edge connectors of the routing trace. Alternatively, a testing device can be connected to a side portion 99 of the sheet 85, where the side portion 99 contains routing lines in connection with each respective trace termination at the edge 100 of the daughter boards 90. The side portion 99 may be diced or cut and discarded after testing has been completed.

The present invention overcomes the expense and waste which can occur in conventional memory arrays by enabling a small number of chips to be tested at once, prior to their insertion into the memory array. Furthermore, the present invention enables the individual daughter boards of the memory module to be replaced by another daughter board prior to inserting one daughter boards into the memory array, so that the fault of one memory chip or daughter board does not result in failure of the entire memory array. Moreover, because all of the daughter boards and memory chips are identical, they may be manufactured and tested, inexpensively.

FIG. 7 shows a perspective view of a memory module 110, including a module substrate 125, daughter boards 115, and memory modules 120, according to one aspect of the invention. The daughter boards 115 are stacked adjacent to each other and substantially aligned, forming a compact parallelepiped memory module 110, thereby creating a dense memory device which can fit within the footprint of many conventional memory devices that had substantially fewer memory locations. Although not illustrated in FIG. 7, it will be appreciated by those of skill in the art that the module substrate 125 can contain one or more means of connection, such as a ball grid array such that it can be connected to another electronic device, such as a processor.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A memory array having a high data bus bandwidths, comprising:
a module substrate;
a plurality of daughter boards edge-mounted to the module substrate, wherein each daughter board of the plurality of daughter boards comprises a front face and a back face opposite the front face, and
at least one memory chip mounted to the front face of each daughter board of the plurality of daughter boards, such that the at least one memory chip is in electrical communication with the module substrate.

2. The memory array of claim 1, wherein the plurality of daughter boards are stacked adjacent to each other such that the front face of at least one daughter board is located adjacent to the back face of at least one other daughter board.

3. The memory array of claim 1, wherein the plurality of daughter boards are stacked together and substantially aligned to form a compact parallelepiped memory module.

4. The memory array of claim 1, wherein the plurality of daughter boards are edge mounted to the module substrate by edge mount solder joints.

5. The memory array of claim 1, wherein the plurality of daughter boards are in wafer form.

6. The memory array of claim 1, wherein the at least one memory chip is mounted to the front face of each daughter board of the plurality of daughter boards such that one side of the at least one memory chip is in electrical communication with the front face of each daughter board.

7. The memory array of claim 1, further comprising an adhesive disposed between the memory chips and the daughter boards.

8. The memory array of claim 1, wherein the plurality of daughter boards comprise routing lines for electrically connecting memory chips mounted thereon to edges of the plurality of daughter boards.

9. The memory array of claim 1, further comprising a thermal spacer located between at least one memory chip and an adjacent daughter board in spaced relationship with the at least one memory chip, wherein the thermal spacer dissipates heat.

10. A method of constructing a memory module comprising:
providing a plurality of daughter boards, wherein each daughter board comprises a front face and a back face opposite the front face;
mounting at least one memory chip on the front face of each daughter board of the plurality of daughter boards; and
edge-mounting the plurality of daughter boards, to a module substrate once at least one memory chip has been mounted on each daughter board, such that the memory chips are in electrical communication with the module substrate thereby forming a memory module.

11. The method according to claim 10, wherein edge-mounting the plurality of daughter boards to the module substrate comprises stacking the plurality of daughter boards adjacent to each other such that the front face of at least one daughter board is located adjacent to the back face of at least one other daughter board.

12. The method of claim 10, wherein edge-mounting the plurality of daughter boards to the module substrate comprises soldering the plurality of daughter boards to the module substrate.

13. The method of claim 10, wherein mounting the memory chips comprises flip-chip bonding the memory chips to the daughter boards.

14. The method of claim 10, further comprising underfilling the memory chips mounted on the plurality of daughter boards.

15. The method of claim 10, further comprising inserting a thermal spacer between at least one memory chip and an adjacent daughter board in spaced relationship with the at least one memory chip, wherein the thermal spacer dissipates heat.

16. The method according to claim 1 1, wherein the plurality of daughter boards are stacked to form a parallelepiped memory module.

17. The method of claim 15, wherein inserting a thermal spacer further comprises edge-mounting the thermal spacer to the module substrate.
